(19) United States
(12) Patent Application Publication
(10) Pub. No.: US 2018/0108686 A1
(43) Pub. Date: Apr. 19, 2018

(54) DISPLAY SUBSTRATE AND MANUFACTURING METHOD THEREOF, DISPLAY PANEL AND DISPLAY DEVICE

(71) Applicant: BOE TECHNOLOGY GROUP CO., LTD., Beijing (CN)

(72) Inventors: Wei LIU, Beijing (CN); Wei LI, Beijing (CN)

(21) Appl. No.: 15/784,398

(22) Filed: Oct. 16, 2017

(30) Foreign Application Priority Data
Oct. 19, 2016 (CN) 201610911365.9

(51) Int. Cl. H01L 27/12

(52) U.S. Cl. CPC H01L 27/1248; H01L 27/3258; H01L 27/124; H01L 27/1262

(57) ABSTRACT

A display substrate and a manufacturing method thereof, a display panel and a display device are provided. The display substrate has a metal overlap region and a metal non-overlap region. The display substrate includes a support substrate, a thin-film transistor and a passivation layer. The thin-film transistor is arranged on the support substrate, and the passivation layer is arranged on the thin-film transistor. A part of the passivation layer is positioned in the metal overlap region and has a first surface. Another part of the passivation layer is positioned in the metal non-overlap region and has a second surface. The first surface and the second surface are positioned in a same plane.

### CROSS REFERENCE

This application is based upon and claims priority to Chinese Patent Application No. 201610911365.9, filed on Oct. 19, 2016, the entire contents thereof are incorporated herein by reference.

### TECHNICAL FIELD

The present disclosure relates to the field of display technologies, and particularly to a display substrate and a manufacturing method thereof, a display panel and a display device.

### BACKGROUND

When a display substrate adopting a 2T1C (two transistors and one capacitor) oxide thin-film transistor is used in a display panel in solution-based process, the conventional display substrate at least requires a single metal overlap. For such an overlapping region, increase of thickness may necessarily form a segment gap with other region. If the segment gap is in a pixel unit, unevenness may occur in inkjet-printed droplet organic material for emitting light above. In this case, uneven display may occur in a single pixel unit. However, a large number of such pixel units may cause overall abnormal color of the display panel.

### SUMMARY

Aiming at at least solving one of technical problems in the prior art, the present disclosure provides a display substrate, a manufacturing method thereof, a display panel and a display device that can prevent poor display caused by a segment gap between a metal overlap region and a metal non-overlap region.

According to a technical solution for solving the technical problem of the present disclosure, there is provided a display substrate. The display substrate has a metal overlap region and a metal non-overlap region. The display substrate includes a support substrate, a thin-film transistor and a passivation layer. The thin-film transistor is arranged on the support substrate, and the passivation layer is arranged on the thin-film transistor.

A part of the passivation layer is positioned in the metal overlap region and has a first surface. Another part of the passivation layer is positioned in the metal non-overlap region and has a second surface. The first surface and the second surface are positioned in the same plane.

As another technical solution, the present disclosure further provides a manufacturing method of a display substrate. The display substrate has a metal overlap region and a metal non-overlap region.

The manufacturing method includes:

forming a thin-film transistor and a gate insulation layer on a support substrate; and

forming a passivation layer on the thin-film transistor.

A part of the passivation layer is positioned in the metal overlap region and has a first surface. Another part of the passivation layer is positioned in the metal non-overlap region and has a second surface. The first surface and the second surface are positioned in the same plane.

As another technical solution, the present disclosure further provides a display panel, which includes a display substrate and an opposite substrate oppositely arranged relative to the display substrate.

The display substrate has a metal overlap region and a metal non-overlap region. The display substrate includes a support substrate, a thin-film transistor and a passivation layer. The thin-film transistor is arranged on the support substrate, and the passivation layer is arranged on the thin-film transistor.

A part of the passivation layer is positioned in the metal overlap region and has a first surface. Another part of the passivation layer is positioned in the metal non-overlap region and has a second surface. The first surface and the second surface are positioned in the same plane.

As another technical solution, the present disclosure further provides a display device, which includes the above display panel. The display panel includes a display substrate and an opposite substrate oppositely arranged relative to the display substrate.

The display substrate has a metal overlap region and a metal non-overlap region. The display substrate includes a support substrate, a thin-film transistor and a passivation layer. The thin-film transistor is arranged on the support substrate, and the passivation layer is arranged on the thin-film transistor.

A part of the passivation layer is positioned in the metal overlap region and has a first surface. Another part of the passivation layer is positioned in the metal non-overlap region and has a second surface. The first surface and the second surface are positioned in the same plane.

### BRIEF DESCRIPTION OF THE DRAWINGS

FIG. 1 is a schematic structural diagram of a display substrate;

FIG. 2 is a scanning electron microscope picture of the display substrate in FIG. 1;

FIG. 3 is a schematic structural diagram of a display substrate according to Embodiment 1 of the present disclosure;

FIG. 4 is a schematic flow diagram of a manufacturing method of a display substrate according to Embodiment 2 of the present disclosure;

FIG. 5 is a schematic structural diagram of Step S1 of the manufacturing method of the display substrate according to Embodiment 2 of the present disclosure;

FIG. 6 is a schematic structural diagram of Step S21 of the manufacturing method of the display substrate according to Embodiment 2 of the present disclosure;

FIG. 7 is a schematic structural diagram of Step S22 of the manufacturing method of the display substrate according to Embodiment 2 of the present disclosure;

FIG. 8 is a schematic structural diagram of Step S23 of the manufacturing method of the display substrate according to Embodiment 2 of the present disclosure;

FIG. 9 is a schematic structural diagram of Step S24 of the manufacturing method of the display substrate according to Embodiment 2 of the present disclosure;

FIG. 10 is a schematic structural diagram of Step S25 of the manufacturing method of the display substrate according to Embodiment 2 of the present disclosure;

FIG. 11 is a schematic structural diagram of Step S26 of the manufacturing method of the display substrate according to Embodiment 2 of the present disclosure;

FIG. 12 is a schematic structural diagram of Step S27 of the manufacturing method of the display substrate according to Embodiment 2 of the present disclosure;

FIG. 13 is a schematic structural diagram of Step S28 of the manufacturing method of the display substrate according to Embodiment 2 of the present disclosure;

FIG. 14 is a schematic structural diagram of Step S3 of the manufacturing method of the display substrate according to Embodiment 2 of the present disclosure; and

FIG. 15 is a schematic structural diagram of Step S4 of the manufacturing method of the display substrate according to Embodiment 2 of the present disclosure.

Reference numbers in the attached drawings: metal overlap region A; metal non-overlap region B; support substrate 1; gate 2; gate insulation layer 3; active layer 4; etching stop layer 5; source via hole 51; drain via hole 52; source 6; drain 7; passivation layer 8; first surface 81; second surface 82; first via hole 83; planarization layer 9; second via hole 91; pixel electrode 10; pixel defining layer 11; groove 111; pixel 12; passivation material layer 13; photoresist layer 14; partly exposed photoresist pattern 141; unexposed photoresist pattern 142; completely exposed photoresist pattern 143.

### DETAILED DESCRIPTION

In order that those skilled in the art better understand the technical solution of the present invention, the following further describes in detail the present invention with reference to the accompanying drawings and embodiments.

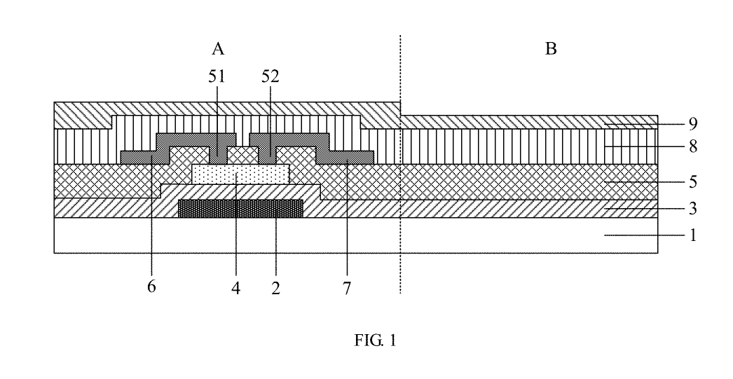

The structure of a display substrate is as shown in FIG. 1. The display substrate includes a support substrate 1, a thin-film transistor and a gate insulation layer 3 positioned on the support substrate 1, a passivation layer 8 on the thin-film transistor, and a planarization layer 9 positioned on the passivation layer 8. The structure of the thin-film transistor includes: a gate 2, an active layer 4, an etching stop layer 5, a source 6 and a drain 7. The gate 2 is positioned on the support substrate 1, the gate insulation layer 3 is positioned on the gate 2, the active layer 4 is positioned on the gate insulation layer 3, and the etching stop layer 5 is positioned on the active layer 4. The etching stop layer 5 is provided with a first via hole 51 and a second via hole 52. The source 6 and the drain 7 are positioned on the etching stop layer 5. The source 6 is connected to the active layer 4 through the first via hole 51, and the drain 7 is connected to the active layer 4 through the second via hole 52.

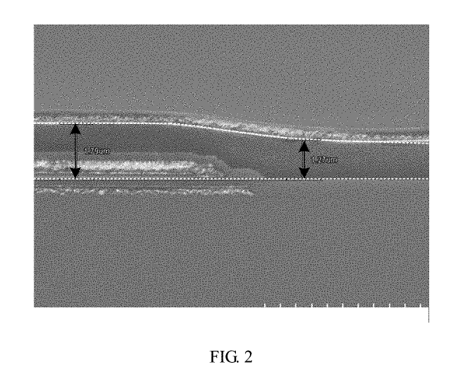

As can be seen from FIG. 1, the display substrate includes a metal overlap region A and a metal non-overlap region B, and the thin-film transistor is positioned in the metal overlap region A. A multilayer structure in the thin-film transistor causes that an upper surface of the passivation layer 8 positioned in the metal overlap region A is higher than that of the passivation layer 8 positioned in the metal non-overlap region B. Therefore, even if the planarization layer 9 is deposited on the passivation layer 8, it is impossible to ensure that an upper surface of the planarization layer 9 positioned in the metal overlap region A is equal, in height, to that of the planarization layer 9 positioned in the metal non-overlap region B because the planarization layer 9 generally is made of a resin material, which is limited in planarization degree. The height of the upper surface of the planarization layer 9 positioned in the metal overlap region A is 1.79 μm, and the height of the upper surface of the planarization layer 9 positioned in the metal non-overlap region B is 1.27 μm (as shown in FIG. 2). However, inkjet-printed materials have a high requirement for the planarization degree. Consequently, the conventional planarization methods cannot satisfy the manufacture of the display panel in solution-based process.

### Embodiment 1

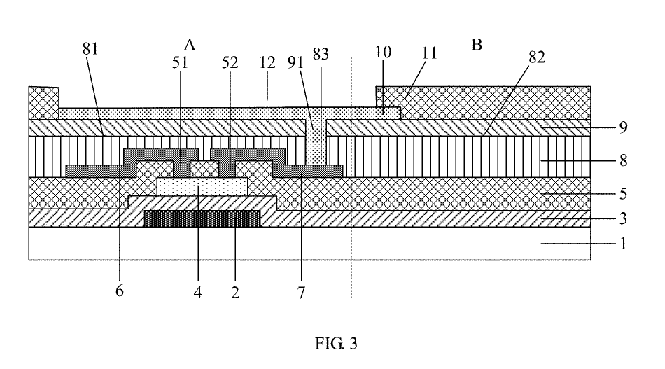

Referring to FIG. 3, this embodiment provides a display substrate, which has a metal overlap region A and a metal non-overlap region B. The display substrate includes a support substrate 1, a thin-film transistor and a passivation layer 8. The thin-film transistor is arranged on the support substrate 1, and the passivation layer 8 is arranged on the thin-film transistor. A part of the passivation layer 8 is positioned in the metal overlap region A and has a first surface 81. Another part of the passivation layer 8 is positioned in the metal non-overlap region B and has a second surface 82. The first surface 81 and the second surface 82 are positioned in the same plane.

Specifically, as shown in FIG. 3, the display substrate further includes a gate insulation layer 3, and the thin-film transistor includes: a gate 2, an active layer 4, an etching stop layer 5, a source 6 and a drain 7. The gate 2 is positioned on the support substrate 1, the gate insulation layer 3 is positioned on the gate 2, the active layer 4 is positioned on the gate insulation layer 3, and the etching stop layer 5 is positioned on the active layer 4. The etching stop layer 5 is provided with a source via hole 51 and a drain via hole 52. The source 6 and the drain 7 are positioned on the etching stop layer 5. The source 6 is connected to the active layer 4 through the source via hole 51, and the drain 7 is connected to the active layer 4 through the drain via hole 52. Specifically, a part of the source 6 is filled in the source via hole 51 to connect the active layer 4, and a part of the drain 7 is filled in the drain via hole 52 to connect the active layer 4.

As can be seen from FIG. 3, a passivation layer 8 is positioned on the source 6 and the drain 7. The passivation layer 8 is provided with a first surface 81 positioned in the metal overlap region A and a second surface 82 positioned in the metal non-overlap region B. The first surface 81 and the second surface 82 are in the same horizontal plane. The objective of such configuration is to ensure no segment gap exists between the first surface 81 and the second surface 82, so that inkjet-printed droplet organic material for emitting light above the passivation layer 8 is positioned in a planar surface. Therefore, the problem of uneven display in a single pixel unit caused by uneven droplet organic material is avoided.

The passivation layer 8 is provided with a first via hole 83, and the display substrate further includes a pixel electrode 10, wherein the pixel electrode 10 is positioned in the first via hole 83 to connect the thin-film transistor. As can be seen from FIG. 3, a part of the pixel electrode 10 is positioned above the passivation layer 8, and another part of the pixel electrode 10 is positioned in the first via hole 83 and is connected to the drain 7 of the thin-film transistor.

The display substrate further includes a planarization layer 9, which is positioned on the passivation layer 8. The planarization layer 9 is provided with a second via hole 91. The pixel electrode 10 is positioned in the first via hole 83 and the second via hole 91 to connect the thin-film transistor. As can be seen from FIG. 3, the first surface 81 and the second surface 82 of the passivation layer 8 are positioned in the same plane. Therefore, the surface of the planarization layer 9 positioned in the metal overlap region A and the surface of the planarization layer 9 positioned in the metal non-overlap region B are also within the same plane. That is, no segment gap exists. The planarization layer 9 is provided with a second via hole 91, which is communicated with the first via hole 83. A part of the pixel electrode 10 is positioned in the second via hole 91 and the first via hole 83. That is, the pixel electrode 10 is connected to the drain 7 in the thin-film transistor through the second via hole 91 and the first via hole 83.

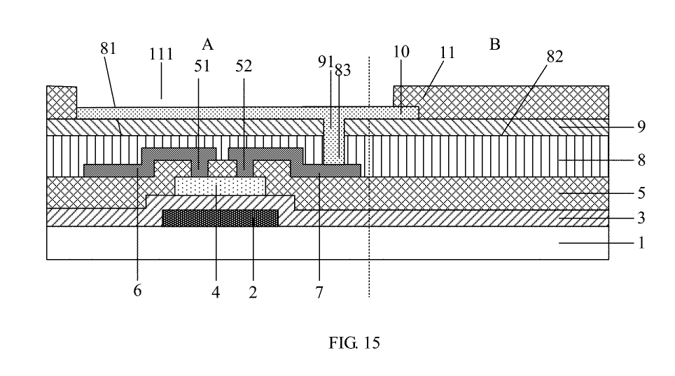

As shown in FIG. 3, the display substrate further includes a pixel defining layer 11 and a pixel 12, wherein the pixel 12 is positioned in the pixel defining layer 11. It is to be understood that each pixel unit is provided with a pixel 12. The pixel 12 is the light-emitting droplet organic material. Specifically, the pixel defining layer 11 is positioned on the planarization layer 9. The pixel defining layer 11 is provided with a plurality of grooves (referring to FIG. 15 as below), wherein each groove is provided with a pixel 12. That is, the light-emitting droplet organic material is positioned in the groove.

The display substrate of this embodiment is provided with a metal overlap region A and a metal non-overlap region B. The display substrate includes a support substrate 1, a thin-film transistor and a passivation layer 8. The thin-film transistor is arranged on the support substrate 1, and the passivation layer 8 is arranged on the thin-film transistor. A part of the passivation layer 8 is positioned in the metal overlap region A and has a first surface 81. Another part of the passivation layer 8 is positioned in the metal non-overlap region B and has a second surface 82. The first surface 81 and the second surface 82 are positioned in the same plane. In this way, a segment gap between the surface of the passivation layer 8 positioned in the metal overlap region A and the surface of the passivation layer 8 positioned in the metal non-overlap region B can be avoided, so that the passivation layer 9 is a plane. Thus, an objective of using an existing planarization material to satisfy manufacturing of a display panel in solution-based process is implemented. Meanwhile, a problem of occurrence of poor display of the display device is avoided.

### Embodiment 2

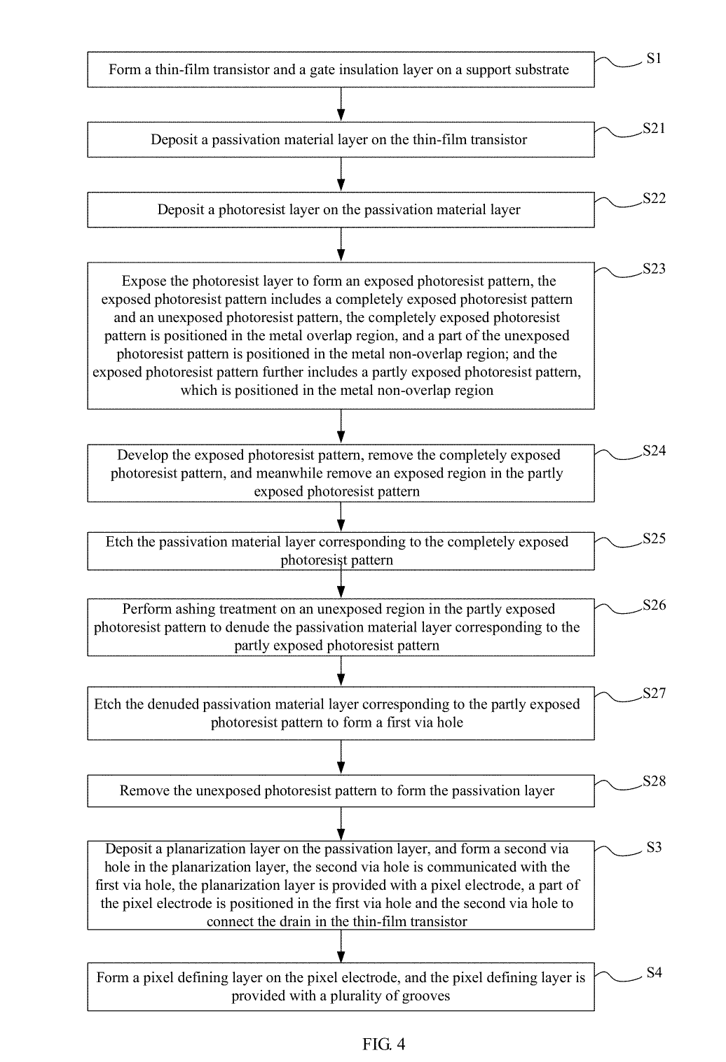

Referring to FIG. 4-FIG. 15, this embodiment provides a manufacturing method of a display substrate, wherein the display substrate is provided with a metal overlap region A and a metal non-overlap region B.

The manufacturing method of the display substrate of this embodiment includes following steps.

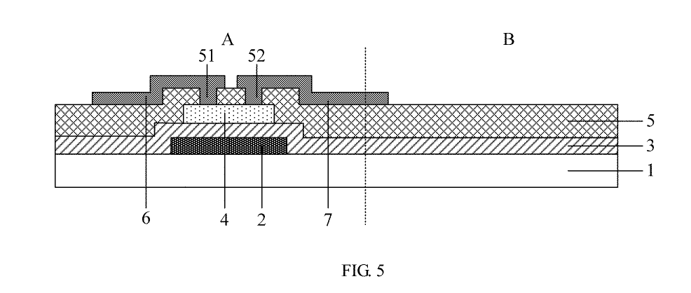

As shown in FIG. 5, in Step S1, a thin-film transistor and a gate insulation layer 3 are formed on a support substrate 1.

Specifically, a gate 2 is formed on the substrate 1, the gate insulation layer 3 is formed on the gate 2, an active layer 4 is formed on the gate insulation layer 3, an etching stop layer 5 is formed on the active layer 4, a source via hole 51 and a drain via hole 52 are formed in the etching stop layer 5, and a source 6 and a drain 7 are formed on the etching stop layer 5. A part of the source 6 is positioned in the source via hole 51 and is connected to the active layer 4 through the source via hole 51, and a part of the drain 7 is positioned in the drain via hole 52 and is connected to the active layer 4 through the drain via hole 52.

In Step S2, a passivation layer 8 is formed on the thin-film transistor.

A part of the passivation layer 8 is positioned in the metal overlap region A and has a first surface 81, another part of the passivation layer 8 is positioned in the metal non-overlap region B and has a second surface 82, and the first surface 81 and the second surface 82 are positioned in the same plane. Step S2 includes following steps.

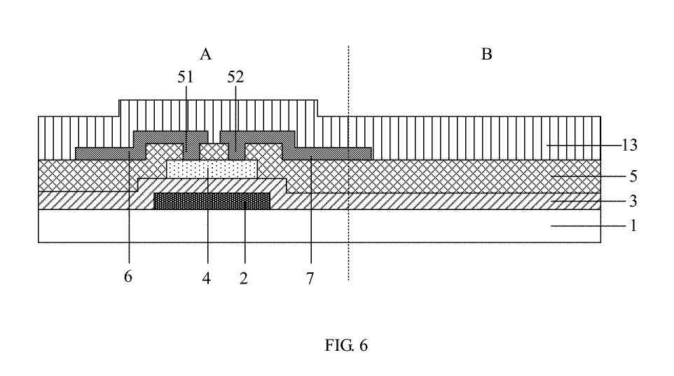

As shown in FIG. 6, in Step S21, a passivation material layer 13 is deposited on the thin-film transistor.

The passivation material layer 13 is deposited on the source 6 and the drain 7. As can be seen from FIG. 6, a segment gap exists between the passivation material layer 13 positioned in the metal overlap region A and the passivation material layer 13 positioned in the metal non-overlap region B.

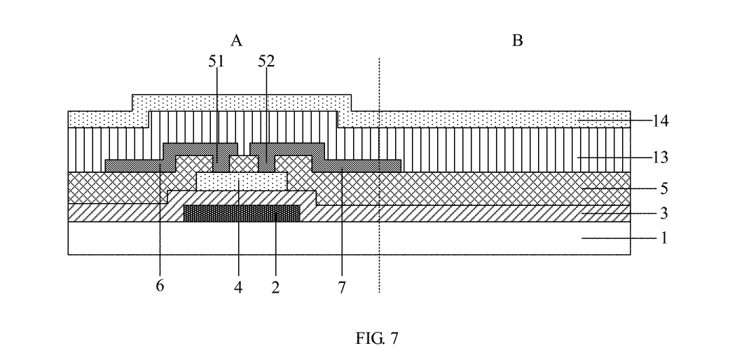

As shown in FIG. 7, in Step S22, a photoresist layer 14 is deposited on the passivation material layer.

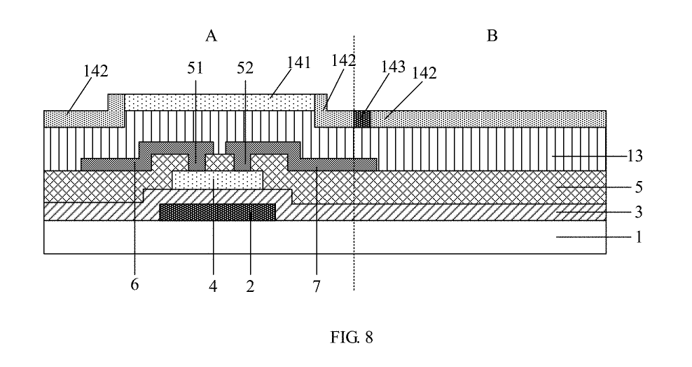

As shown in FIG. 8, in Step S23, the photoresist layer 14 is exposed to form an exposed photoresist pattern. The exposed photoresist pattern includes a completely exposed photoresist pattern 143 and an unexposed photoresist pattern 142. The completely exposed photoresist pattern 143 is positioned in the metal non-overlap region B, and a part of the unexposed photoresist pattern 142 is positioned in the metal non-overlap region B. The exposed photoresist pattern further includes a partly exposed photoresist pattern 141, which is positioned in the metal overlap region A.

Referring to FIG. 8, the partly exposed photoresist pattern 141 corresponds to the “projecting” passivation material layer 13 positioned in the metal overlap region A, and the completely exposed photoresist pattern 143 is positioned in the metal non-overlap region B and corresponds to a part of the drain 7. It is to be understood that the pattern obtained by removing the completely exposed photoresist pattern 143 and the partly exposed photoresist pattern 141 from the photoresist layer 14 is the unexposed photoresist pattern 142.

It is to be understood that in Step S23 the photoresist layer 14 may be exposed using a half-tone mask or a gray-tone mask to form the completely exposed photoresist pattern 143, the unexposed photoresist pattern 142 and the partly exposed photoresist pattern 141.

In Step S24, the exposed photoresist pattern is developed, the completely exposed photoresist pattern 143 is removed, and meanwhile an exposed region in the partly exposed photoresist pattern 141 is removed.

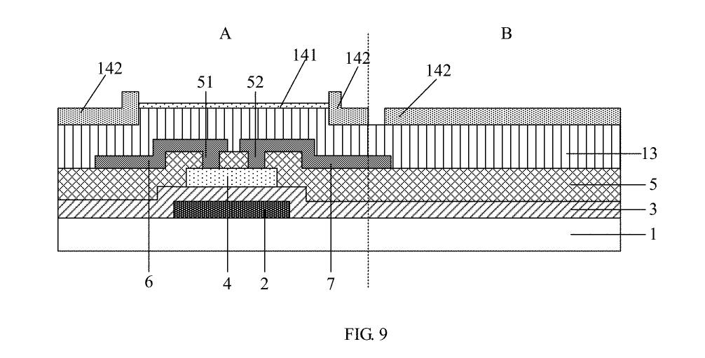

As shown in FIG. 9, the completely exposed photoresist pattern 143 is wholly removed, and the exposed region in the partly exposed photoresist pattern 141 is removed, but an unexposed region is still reserved in the partly exposed photoresist pattern 141.

In Step S25, the passivation material layer 13 corresponding to the completely exposed photoresist pattern 143 is etched.

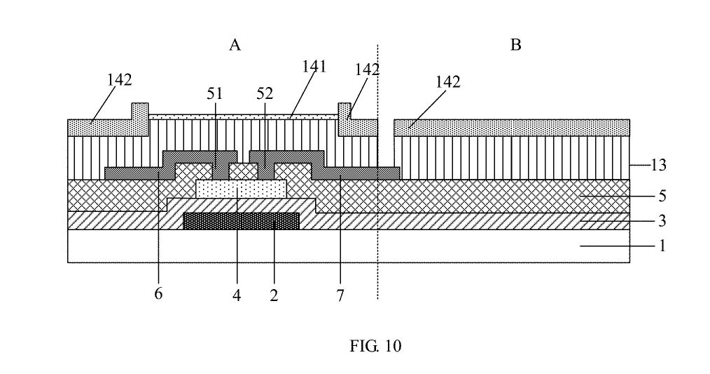

As shown in FIG. 10, the passivation material layer 13 corresponding to the completely exposed photoresist pattern 143 has been denuded. Therefore, the passivation material layer 13 corresponding to the completely exposed photoresist pattern 143 is etched so that a first via hole 83 is formed in the passivation material layer 13 and thus a part of the drain 7 is denuded.

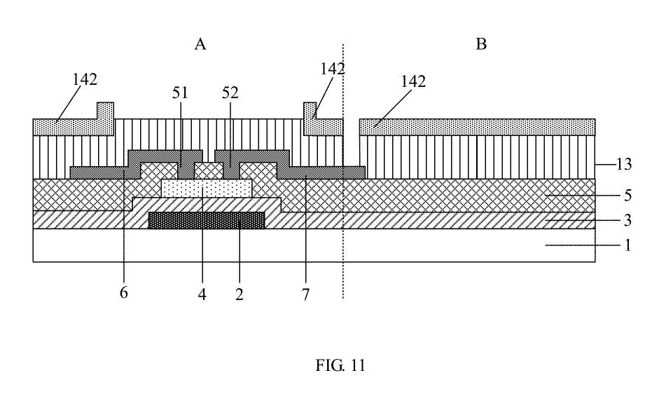

In Step S26, ashing treatment is performed on an unexposed region in the partly exposed photoresist pattern 141 to denude the passivation material layer 13 corresponding to the partly exposed photoresist pattern 141. As shown in FIG. 11, the unexposed region in the partly exposed photoresist pattern 141 is completely removed by using the ashing process.

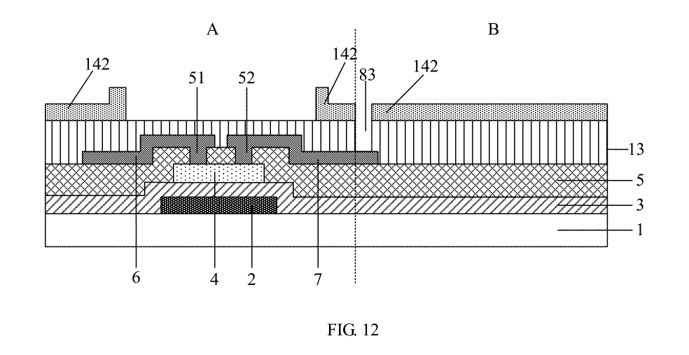

In Step S27, the denuded passivation material layer 13 corresponding to the partly exposed photoresist pattern 141 is etched so that the surface of the passivation material layer 13 corresponding to the partly exposed photoresist pattern 141 is equal, in height, to the surface of the passivation material layer 13 positioned in the metal non-overlap region B, as shown in FIG. 12.

In Step S28, the unexposed photoresist pattern 142 is removed to form the passivation layer 8.

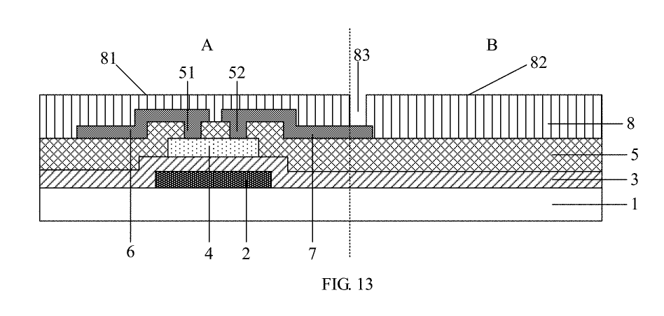

As shown in FIG. 13, the unexposed photoresist pattern 142 on the passivation material layer 13 is completely removed to form the passivation layer 8 having the first via hole 83. The first surface 81 of the passivation layer 8 positioned in the metal overlap region A and the second surface 82 of the passivation layer 8 positioned in the metal non-overlap region B are positioned in the same plane.

Alternatively, after Step S2, the manufacturing method of this embodiment further includes following steps.

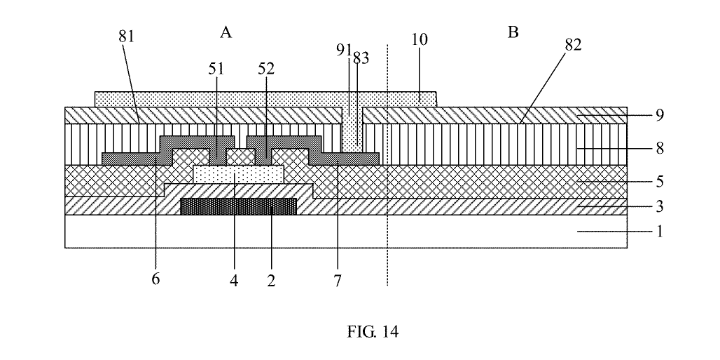

As shown in FIG. 14, in Step S3, a planarization layer 9 is deposited on the passivation layer 8, and a second via hole 91 is formed in the planarization layer 9. The second via hole 91 is arranged correspondingly and communicated with the first via hole 83. The planarization layer 9 is provided with a pixel electrode 10. A part of the pixel electrode 10 is positioned in the first via hole 83 and the second via hole 91 to connect the drain 7 in the thin-film transistor.

Specifically, a planarization material layer is deposited on the passivation layer 8, and the planarization material layer is exposed, developed and etched so that the planarization layer 9 having the second via hole 91 is formed on the passivation layer 8. It is to be understood that the first via hole 83 and the second via hole 91 actually form a via hole penetrating through the passivation layer 8 and the planarization layer 9.

As shown in FIG. 15, in Step S4, a pixel defining layer 11 is formed on the pixel electrode 10, and the pixel defining layer 11 is provided with a plurality of grooves 111.

In Step S5, a light-emitting droplet organic material is filled in the grooves 111 of the pixel defining layer 11, and thus a pixel 12 is formed, as shown in FIG. 3.

The manufacturing method of the display substrate of this embodiment is used for manufacturing the display substrate of Embodiment 1, and reference may be made to the display substrate of Embodiment 1 for a detailed description thereof, which is not repeated any more herein.

The manufacturing method of the display substrate of this embodiment is used for manufacturing the display substrate of Embodiment 1, which can avoid a segment gap between the surface of the passivation layer 8 positioned in the metal overlap region A and the surface of the passivation layer 8 positioned in the metal non-overlap region B, so that the passivation layer 9 is a plane. Thus, an objective of using an existing planarization material to satisfy manufacturing of the display panel in solution-based process is implemented. Meanwhile, a problem of occurrence of poor display of the display device is avoided.

### Embodiment 3

This embodiment provides a display panel, which includes the display substrate of Embodiment 1 and an opposite substrate oppositely arranged relative to the display substrate.

The display panel of this embodiment includes the display substrate of Embodiment 1, and can avoid a segment gap between the surface of the passivation layer 8 positioned in the metal overlap region A and the surface of the passivation layer 8 positioned in the metal non-overlap region B, so that the passivation layer 9 is a plane. Thus, an objective of using an existing planarization material to satisfy manufacturing of the display panel in solution-based process is implemented. Meanwhile, a problem of occurrence of poor display of the display device is avoided.

### Embodiment 4

This embodiment provides a display device, which includes the display panel of Embodiment 3. The display device may be any product or component having a display function, such as a liquid crystal display panel, an electronic paper display, a mobile phone, a tablet computer, a TV set, a display, a notebook computer, a digital photo frame, a navigation device and so on.

Including the display panel of Embodiment 3, the display device of this embodiment can avoid a segment gap between the surface of the passivation layer 8 positioned in the metal overlap region A and the surface of the passivation layer 8 positioned in the metal non-overlap region B, so that the passivation layer 9 is a plane. Thus, an objective of using an existing planarization material to satisfy manufacturing of the display panel in solution-based process is implemented. Meanwhile, a problem of occurrence of poor display of the display device is avoided.

In the display substrate and the manufacturing method thereof, the display panel and the display device provided by the present disclosure, the display substrate is provided with a metal overlap region and a metal non-overlap region, the display substrate includes a support substrate, a thin-film transistor and a passivation layer. The thin-film transistor is arranged on the support substrate, and the passivation layer is arranged on the thin-film transistor. A part of the passivation layer is positioned in the metal overlap region and has a first surface. Another part of the passivation layer is positioned in the metal non-overlap region and has a second surface. The first surface and the second surface are positioned in the same plane. In this way, a segment gap between the surface of the passivation layer positioned in the metal overlap region and the surface of the passivation layer positioned in the metal non-overlap region can be avoided, so that the passivation layer is a plane. Thus, an objective of using an existing planarization material to satisfy manufacturing of the display panel in solution-based process is implemented. Meanwhile, a problem of occurrence of poor display of the display device is avoided.

It is to be understood that the foregoing implementations are merely exemplary implementations to describe the principle of the present disclosure. However, the present disclosure is not limited thereto. To those of ordinary skill in the art, various modifications and improvements may be made without departing from the spirit and essence of the present invention, and these modifications and improvements are also deemed to be within the scope of protection of the present invention.

What is claimed is:

1. A display substrate, wherein the display substrate has a metal overlap region and a metal non-overlap region; the display substrate comprising: a support substrate, a thin-film transistor and a passivation layer, wherein the thin-film transistor is arranged on the support substrate, and the passivation layer is arranged on the thin-film transistor; and
wherein a part of the passivation layer is positioned in the metal overlap region and has a first surface, another part of the passivation layer is positioned in the metal non-overlap region and has a second surface, and the first surface and the second surface are positioned in a same plane.

2. The display substrate according to claim 1, wherein the passivation layer is provided with a first via hole, and the display substrate further comprises a pixel electrode; wherein
the pixel electrode is positioned in the first via hole to connect the thin-film transistor.

3. The display substrate according to claim 2, further comprising a planarization layer, wherein the planarization layer is positioned on the passivation layer, and the planarization layer is provided with a second via hole; and
the pixel electrode is positioned in the first via hole and the second via hole to connect the thin-film transistor.

4. The display substrate according to claim 3, further comprising a pixel defining layer and a pixel, wherein the pixel is positioned in the pixel defining layer.

5. A manufacturing method of a display substrate, wherein the display substrate has a metal overlap region and a metal non-overlap region;
the manufacturing method comprises:
forming a thin-film transistor and a gate insulation layer on a support substrate; and
forming a passivation layer on the thin-film transistor;
wherein a part of the passivation layer is positioned in the metal overlap region and has a first surface, another part of the passivation layer is positioned in the metal non-overlap region and has a second surface, and the first surface and the second surface are positioned in a same plane.

6. The manufacturing method of the display substrate according to claim 5, wherein the step of forming a passivation layer on the thin-film transistor comprises:
depositing a passivation material layer on the thin-film transistor;
depositing a photoresist layer on the passivation material layer;
exposing the photoresist layer to form an exposed photoresist pattern, the exposed photoresist pattern comprising a completely exposed photoresist pattern and an unexposed photoresist pattern, the completely exposed photoresist pattern being positioned in the metal non-overlap region, and the unexposed photoresist pattern being positioned in the metal non-overlap region;
developing the exposed photoresist pattern, and removing the completely exposed photoresist pattern;
etching the passivation material layer positioned in the metal non-overlap region to form a first via hole; and
removing the unexposed photoresist pattern.

7. The manufacturing method of the display substrate according to claim 6, wherein the exposed photoresist pattern further comprises a partly exposed photoresist pattern, the partly exposed photoresist pattern is positioned in the metal overlap region;
when developing the exposed photoresist pattern and removing the completely exposed photoresist pattern, the method further comprises: removing an exposed region in the partly exposed photoresist pattern;
after etching the passivation material layer positioned in the metal non-overlap region, the method further comprises: performing ashing treatment on an unexposed region of the partly exposed photoresist pattern to denude the passivation material layer corresponding to the partly exposed photoresist pattern; and
etching the denuded passivation material layer corresponding to the partly exposed photoresist pattern.

8. A display panel, comprising:
a display substrate and an opposite substrate oppositely arranged relative to the display substrate;
wherein the display substrate has a metal overlap region and a metal non-overlap region; the display substrate comprises a support substrate, a thin-film transistor and a passivation layer, the thin-film transistor is arranged on the support substrate, and the passivation layer is arranged on the thin-film transistor; and
wherein a part of the passivation layer is positioned in the metal overlap region and has a first surface, another part of the passivation layer is positioned in the metal non-overlap region and has a second surface, and the first surface and the second surface are positioned in a same plane.

9. The display panel according to claim 8, wherein the passivation layer is provided with a first via hole, and the display substrate further comprises: a pixel electrode; wherein
the pixel electrode is positioned in the first via hole to connect the thin-film transistor.

10. The display panel according to claim 9, wherein the display substrate further comprises a planarization layer, the planarization layer is positioned on the passivation layer, and the planarization layer is provided with a second via hole; and
the pixel electrode is positioned in the first via hole and the second via hole to connect the thin-film transistor.

11. The display panel according to claim 10, wherein the display substrate further comprises a pixel defining layer and a pixel, and the pixel is positioned in the pixel defining layer.

12. A display device, comprising the display panel according to claim 8.

13. The display device according to claim 12, wherein the passivation layer is provided with a first via hole, and the display substrate further comprises: a pixel electrode; wherein
the pixel electrode is positioned in the first via hole to connect the thin-film transistor.

14. The display device according to claim 13, wherein the display substrate further comprises a planarization layer, the planarization layer is positioned on the passivation layer, and the planarization layer is provided with a second via hole; and
the pixel electrode is positioned in the first via hole and the second via hole to connect the thin-film transistor.

15. The display device according to claim 14, wherein the display substrate further comprises a pixel defining layer and a pixel, and the pixel is positioned in the pixel defining layer.
